(19) United States
(12) Patent Application Publication
(10) Pub. No.: US 2004/0089901 A1
(43) Pub. Date: May 13, 2004

(54) Semiconductor integrated circuit and semiconductor substrate of the same

(76) Inventors: Hiroaki Ohkubo, Kanagawa (JP); Hiroaki Kikuchi, Kanagawa (JP); Masayuki Furumiya, Kanagawa (JP); Ryouta Yamamoto, Kanagawa (JP); Yasutaka Nakashiba, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/695,969

(22) Filed: Oct. 29, 2003

(30) Foreign Application Priority Data
Oct. 31, 2002 (JP) 2002-318910

(51) Int. Cl. H01L 27/01

(52) U.S. Cl. 257/347

(57) ABSTRACT

In a semiconductor integrated circuit, a P-type epitaxial layer is provided on the entire surface of a P-type bulk substrate. The resistivity of the P-type bulk substrate is set to 1000 Ω·cm, and the thickness and the resistivity of the P-type epitaxial layer is set to 5 μm and 10 Ω·cm, respectively. Then, a digital section and an analog section are provided remote from each other on the P-type epitaxial layer, where a digital circuit and an analog circuit are formed on the digital section and analog section, respectively. Further a device isolation region reaching the P-type bulk substrate is formed in a region between the digital section and analog section of the P-type epitaxial layer.

### BACKGROUND OF THE INVENTION

1. Field of the Invention

The present invention relates to a semiconductor integrated circuit that inhibits noise to propagate in a substrate and a semiconductor substrate thereof.

2. Description of the Related Art

Conventionally, an analog/digital hybrid type integrated circuit, where an analog circuit and a digital circuit are formed on a same substrate, has been developed. The analog/digital hybrid type integrated circuit has a problem that noise generated accompanied by the operation of the digital circuit reaches the analog circuit via the substrate to cause malfunction in the analog circuit. Further, when the analog circuit outputs a signal of large amplitude, there are cases where the noise accompanied by the operation of the analog circuit cause malfunction in the digital circuit.

FIG. 1 is a cross-sectional view showing a conventional analog/digital hybrid type integrated circuit. As shown in FIG. 1, a P-type semiconductor substrate 101 having the resistivity of 10 Ω·cm, for example, is provided for the conventional integrated circuit and a digital section 102 and an analog section 103 are provided on the surface of the P-type semiconductor substrate 101. The digital circuit and the analog circuit are formed on the digital section 102 and the analog section 103, respectively. FIG. 1 shows a p⁺ diffusion layer 102a as a part of the digital circuit and a p⁺ diffusion layer 103a as a part of the analog circuit. Noise 104 generated in the p⁺ diffusion layer 102a of the digital circuit propagates in the P-type semiconductor substrate 101 to reach the p⁺ diffusion layer 103a of the analog circuit. As a result, malfunction occurs in the analog circuit.

To solve the problem, an SOI (Silicon On Insulator) structure substrate could be used as the semiconductor substrate of the analog/digital hybrid type integrated circuit. In the SOI structure substrate, a buried insulator is provided on the substrate, a semiconductor layer is provided on the buried insulator, and thus the substrate and the semiconductor layer are isolated by the buried insulator. Therefore, low frequency noise to propagate from the semiconductor layer to the substrate is inhibited, and consequently, the low frequency noise is inhibited to propagate between the digital circuit and analog circuit via the substrate.

However, since the buried insulator of the SOI structure substrate is thin and capacitive coupling is performed between the substrate and the semiconductor layer, it is impossible to fully block high frequency noise having a relatively high frequency, which a digital module generates. Furthermore, there is also a problem that a manufacturing cost is high that is economically disadvantageous because the manufacturing of the SOI structure substrate requires a particular process for forming the buried insulator.

For this reason, Japanese Patent Laid-Open No. 2001-345428, for example, discloses a technique that a substrate having high resistance (hereinafter, referred to as a highly resistive substrate) is used as the substrate and integrated circuits are formed on the surface of the highly resistive substrate.

FIGS. 2A and 2B are a plan view and a cross-sectional view showing the conventional analog/digital hybrid type integrated circuit, respectively. As shown in FIGS. 2A and 2B, the conventional integrated circuit is provided with a P-type highly resistive substrate 111. Then, n-wells 112, 113 are formed remote from each other on the surface of the highly resistive substrate 111, and a p-well 114 is formed on the surface of the n-well 112. Then, an analog circuit region 115 is provided on the surface of the p-well 114, and a digital circuit region 116 is provided on the surface of the n-well 113. Since the analog/digital hybrid type integrated circuit uses the highly resistive substrate 111 as the substrate, the propagation of noise between the analog circuit region 115 and digital circuit region 116 in the substrate is inhibited.

Still further, Japanese Patent Laid-Open No. 2002-134702, for example, also discloses a technique that a regular semiconductor substrate is used as the substrate, a highly resistive semiconductor layer is provided on the semiconductor substrate, and the digital circuit and analog circuit are formed remote from each other on the surface of the highly resistive semiconductor layer. In addition, in the prior art, a well for noise barrier is provided on the surface of the semiconductor substrate in a region corresponding to an area between the digital circuit and analog circuit. Japanese Patent Laid-Open No. 2002-134702 describes that the noise propagation can be inhibited by increasing the resistance of the semiconductor layer and providing the well for noise barrier.

However, the above-described prior art has the following problems. In the technique described in Japanese Patent Laid-Open No. 2001-345428, elements are directly fabricated on the surface of the highly resistive substrate to form the integrated circuit. Further, in the technique described in Japanese Patent Laid-Open No. 2002-134702, elements are directly fabricated on the surface of the highly resistive semiconductor layer to form the integrated circuit. For this reason, it is impossible to directly apply the technique of forming integrated circuit on the surface of the regular semiconductor substrate, and it is necessary to change process conditions such as ion implantation conditions and the impurity concentration of the well. In other words, the platform of a conventional device process needs to be changed.

Accordingly, it is necessary to newly develop a process and a manufacturing line in order to actually manufacture the analog/digital hybrid type integrated circuit described in Japanese Patent Laid-Open No. 2001-345428 and No. 2002-134702, which involves enormous cost and time.

### SUMMARY OF THE INVENTION

An object of the present invention is to provide a semiconductor integrated circuit that can be manufactured by directly using the platform of conventional device process and inhibits the noise propagating in the substrate, and a semiconductor substrate thereof.

A semiconductor integrated circuit according to the present invention has a support substrate, a semiconductor layer that is formed on the entire surface of the support substrate and has a lower resistivity than that of the support substrate, and first and second circuit sections formed in the semiconductor layer in an electrically isolated state from each other.

In the present invention, by making the resistivity of the semiconductor layer equal to the resistivity of the conventional semiconductor substrate, conventional process conditions can be directly applied when forming the first and second circuit sections. Further, the first and second circuit sections are electrically isolated from each other in the semiconductor layer, which inhibits the noise to propagate in the semiconductor layer. Additionally, by using the support substrate having higher resistivity than that of the semiconductor layer, the noise propagation in the substrate is inhibited. Consequently, it is not necessary to change the platform of the conventional device process and the development of new process and production line is not required, which makes it possible to obtain the semiconductor integrated circuit that is low cost and prevents malfunction due to noise. Note that the support substrate means a substrate that has a predetermined rigidity and strength, and is freestanding on its own.

Furthermore, it is preferable that the resistivity of the support substrate is 20 times or more the resistivity of the semiconductor layer, and more preferably, it is 50 times or more. Thus, noise electric current flowing in the support substrate is effectively inhibited while the resistivity of the semiconductor layer is maintained in a range where the platform of the conventional device process can be used.

Furthermore, it is preferable that the semiconductor layer is formed on the support substrate by epitaxial growth. Thus, the semiconductor layer is easily formed on the entire surface of the support substrate.

Moreover, the digital circuit and analog circuit may be formed on the first circuit section and the second circuit section, respectively. Thus, high frequency noise accompanied by the drive of digital circuit is prevented from affecting the operation of analog circuit.

A semiconductor substrate according to the present invention is the semiconductor substrate on which the first and second circuit sections are formed to compose the semiconductor integrated circuit. The semiconductor substrate has a support substrate and a semiconductor layer. The semiconductor layer is formed on the entire surface of the support substrate and has a lower resistivity than that of the support substrate, and where the first and second circuit sections are electrically isolated from each other and formed in.

According to the present invention, by reducing the resistivity of the semiconductor layer than the resistivity of the support substrate, the semiconductor integrated circuit, where the reduction of noise propagation in the support substrate is achieved, can be manufactured without changing the platform of the conventional device process.

### BRIEF DESCRIPTION OF THE DRAWINGS

FIG. 1 is the cross-sectional view showing the conventional analog/digital hybrid type integrated circuit.

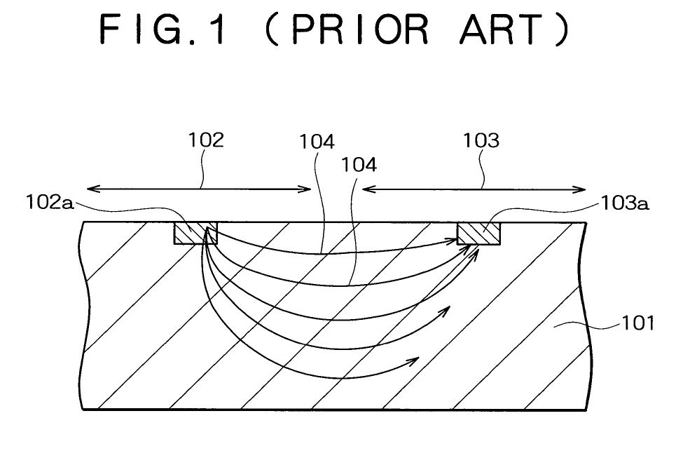

FIG. 2A is a plan view showing the conventional analog/digital hybrid type integrated circuit, and 2B is the cross-sectional view thereof.

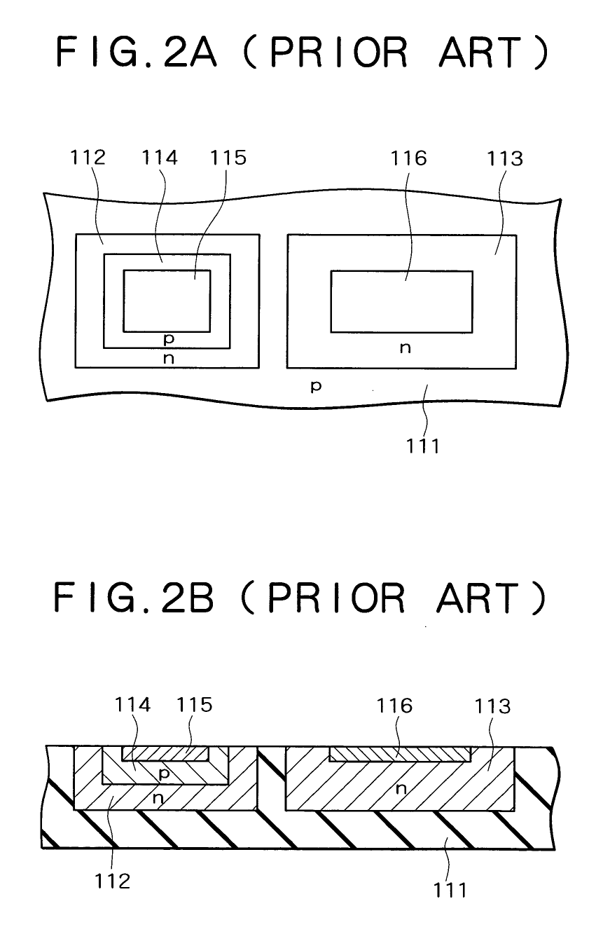

FIG. 3 is a cross-sectional view showing the semiconductor integrated circuit according to the embodiment of the present invention.

FIG. 4 is a graph showing the effect that the resistivity of the support substrate causes to the noise propagation by taking the resistivity of support substrate on the axis of abscissas and propagation characteristic of the noise in the support substrate on the axis of ordinates.

### PREFERRED EMBODIMENT OF THE INVENTION

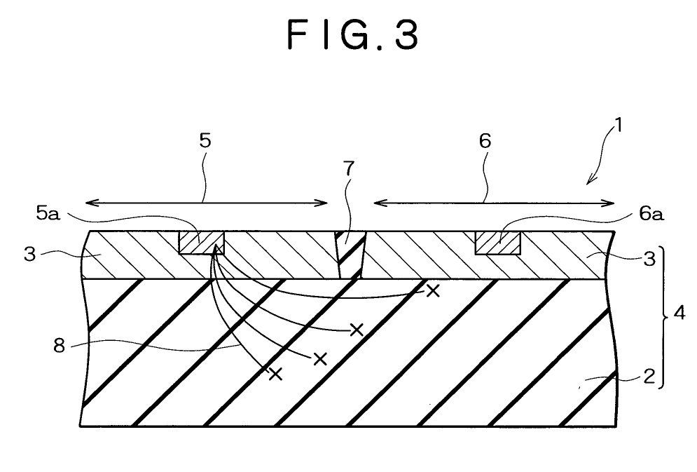

The preferred embodiment of the present invention will be described with reference to the accompanying drawings. FIG. 3 is the cross-sectional view showing the semiconductor integrated circuit according to this embodiment. As shown in FIG. 3, the semiconductor integrated circuit 1 of this embodiment is the analog/digital hybrid type integrated circuit. A P-type bulk substrate 2 is provided in the semiconductor integrated circuit 1. The P-type bulk substrate 2 is a silicon substrate, for example, whose thickness and resistivity are 0.7 mm and 1000 Ω·cm, respectively, for example.

A P-type epitaxial layer 3 is formed on the entire surface of the P-type bulk substrate 2. The P-type epitaxial layer 3 is formed by performing epitaxial growth onto a P-type silicon layer with a CVD method (Chemical Vapor Deposition method) using source gas of silane series. The thickness of the P-type epitaxial layer 3 is 5 μm, for example, and the resistivity is approximately equal to the resistivity of the conventional semiconductor substrate, which is 10 Ω·cm for example. The impurity concentration of the P-type bulk substrate 2 is one hundredth or less the impurity concentration of the P-type epitaxial layer 3, for example. The P-type bulk substrate 2 and the P-type epitaxial layer 3 essentially consist the semiconductor substrate 4 according to this embodiment.

Then, a digital section 5, where the digital circuit is formed, is provided on the surface of the P-type epitaxial layer 3, and an analog section 6, where the analog circuit is formed, is provided remote from the digital section 5. The digital circuit and analog circuit are integrated circuits where elements such as CMOS are formed, for example. Note that FIG. 3 shows only one each of p⁺ diffusion layers 5a, 6a as the digital circuit and analog circuit, respectively. In a region between the digital section 5 and analog section 6 of the P-type epitaxial layer 3, a device isolation region 7 reaching the P-type bulk substrate 2 is provided.

The reason for limiting the numerical values in the constituent of the present invention will be described as follows.

The Resistivity of the Support Substrate: 20 Times or More the Resistivity of the Semiconductor Layer

The semiconductor integrated circuit of the present invention is manufactured directly using the process conditions of the conventional semiconductor integrated circuit, so that it is necessary to approximately match the resistivity of the semiconductor layer with the resistivity of the conventional semiconductor substrate. Then, it is preferable to set the resistivity of the support substrate as high as possible to prevent noise from propagating in the support substrate. If the resistivity of the support substrate is set 20 times or more the resistivity of the semiconductor layer, the resistivity of the support substrate can be sufficiently high while the resistivity of the semiconductor layer remains a value at which the conventional process conditions are usable, and thus the noise propagation is surely prevented. Therefore, it is preferable that the resistivity of the support substrate is 20 times or more the resistivity of the semiconductor layer. More preferably, it is 50 times or more.

Next, the operation of the semiconductor integrated circuit 1 according to the embodiment will be described. When the digital circuit in the digital section 5 starts operation, noise 8 occurs from the p⁺ diffusion layer 5a, for example, accompanied by the operation. However, since the resistivity of the P-type bulk substrate 2 is as sufficiently high as 1000 Ω·cm, the noise 8 does not propagate in the P-type bulk substrate 2 to reach the analog section 6. Accordingly, the analog circuit in the analog section 6 does not cause malfunction due to the noise 8. Further, in the case where the analog circuit outputs a signal having large amplitude, although the noise occurs from the p⁺ diffusion layer 6a accompanied by the output, the noise does not propagate in the P-type bulk substrate 2 to reach the digital section 5 because the P-type bulk substrate 2 is in high resistance. Thus, the digital circuit does not cause malfunction due to the noise.

In addition, since the device isolation region 7 reaching the P-type bulk substrate 2 is provided in the region between the digital section 5 and analog section 6 of the P-type epitaxial layer 3, the digital section 5 and analog section 6 are electrically isolated from each other. For this reason, the noise 8 is inhibited to propagate in the P-type epitaxial layer 3 as well.

In this embodiment, as described, setting the P-type bulk substrate 2 to the high resistance inhibits the noise to propagate between the digital section 5 and analog section 6. Further, since the P-type epitaxial layer 3 has the resistivity equal to that of the conventional semiconductor substrate, process conditions such as the ion implantation conditions and the well concentration can be set to the same conditions as the conventional process conditions when manufacturing the digital circuit and analog circuit. Thus, it is not necessary to change a conventional device platform, and there is no need to develop new process conditions, or develop and adjust a production line in order to manufacture the semiconductor integrated circuit 1. Therefore, time for the development and adjustment is not needed, and the semiconductor integrated circuit 1 can be manufactured at a low cost and in short time.

Note that this embodiment has shown an example where the P-type bulk substrate 2 made of P-type silicon was used as the support substrate, but the present invention is not limited to this. It is enough that the support substrate has a higher resistivity than that of the semiconductor layer. For example, it may be any one of an N-type silicon substrate, a substrate made of semiconductor material other than silicon, and a substrate made of insulating material such as glass.

Furthermore, although an example has been shown where the P-type epitaxial layer 3 as the semiconductor layer was formed by the CVD method, the present invention is not limited to this. For example, ion implantation may be conducted on the entire surface of the P-type bulk substrate 2, and thus forming the semiconductor layer having a lower resistivity than that of the P-type bulk substrate 2. Moreover, various kinds of circuit may be formed as the digital circuit and analog circuit. Still further, the present invention is also effective in inhibiting the noise propagation between digital circuits and the noise propagation between analog circuits.

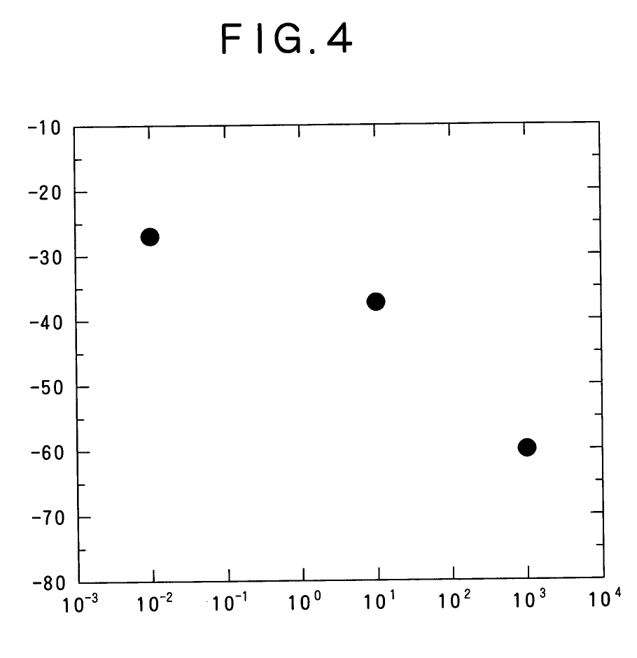

In the following, the effects of the present invention will be specifically described in comparison with a comparative example that departs from the scope of what is claimed by the invention. FIG. 4 is the graph showing the effect that the resistivity of the support substrate causes to the noise propagation by taking the resistivity of support substrate on the axis of abscissas and propagation characteristic of the noise in the support substrate on the axis of ordinates. A plurality of the semiconductor integrated circuits as shown in the above-described embodiment were manufactured. At this point, the resistivity of the P-type bulk substrates were made different from each other among the plurality of semiconductor integrated circuits, and the affect that the resistivity of the support substrate causes to the noise propagation were inspected.

Note that the thickness of the P-type bulk substrates was set to 0.7 mm, and the thickness and the resistivity of the P-type epitaxial layers were set to 5 μm and 10 Ω·cm, respectively. Then, the P-type diffusion layers were formed on two regions of the P-type epitaxial layer, which were remote by 20 μm from each other, and the noise propagation characteristic between the P-type diffusion layers was measured. A measurement mode was set to S21.

As shown in FIG. 4, the noise propagation quantity between the P-type diffusion layers reduced as the resistivity of the P-type bulk substrate as the support substrate became higher. Practically, the noise propagation characteristic is −40 dB (1/100) or less, preferably. Consequently, as shown in FIG. 4, in the case where the resistivity of the P-type epitaxial layer is 10 Ω·cm, the noise propagation characteristic is −60 dB when the resistivity of the P-type bulk substrate (support substrate) is 1000 Ω·cm, and thus the noise propagation is inhibited to a practically sufficient level.

What is claimed is:

1. A semiconductor integrated circuit, comprising:
a support substrate;
a semiconductor layer that is formed on the entire surface of said support substrate and has a lower resistivity than the resistivity of said support substrate; and
first and second circuit sections formed in the semiconductor layer in an electrically isolated state from each other.

2. The semiconductor integrated circuit according to claim 1, wherein the resistivity of said support substrate is 20 times or more the resistivity of said semiconductor layer.

3. The semiconductor integrated circuit according to claim 2, wherein the resistivity of said support substrate is 50 times or more the resistivity of said semiconductor layer.

4. The semiconductor integrated circuit according to claim 1, wherein said semiconductor layer is formed on said support substrate by epitaxial growth.

5. The semiconductor integrated circuit according to claim 1, wherein a digital circuit is formed on said first circuit section, and an analog circuit is formed on said second circuit section.

6. A semiconductor substrate, where a first circuit section and a second circuit section are formed on the surface to compose a semiconductor integrated circuit, said substrate comprising:
a support substrate; and
a semiconductor layer that is formed on the entire surface of the support substrate, has a lower resistivity than the resistivity of said support substrate, and where said first and second circuit sections are electrically isolated from each other and formed in.

7. The semiconductor substrate according to claim 6, wherein the resistivity of said support substrate is 20 times or more the resistivity of said semiconductor layer.

8. The semiconductor substrate according to claim 7, wherein the resistivity of said support substrate is 50 times or more the resistivity of said semiconductor layer.

9. The semiconductor substrate according to claim 6, wherein said semiconductor layer is formed on said support substrate by epitaxial growth.

10. The semiconductor substrate according to claim 6, wherein a digital circuit is formed on said first circuit section, and an analog circuit is formed on said second circuit section.
